(19) United States
(12) Patent Application Publication
(10) Pub. No.: US 2001/0018270 A1
(43) Pub. Date: Aug. 30, 2001

(54) Slurry for chemical mechanical polishing

(76) Inventors: Yasuaki Tsuchiya, Tokyo (JP); Tetsuyuki Itakura, Tokyo (JP); Shin Sakurai, Tokyo (JP)

Correspondence Address: Paul J. Esatto, Jr., Scully, Scott, Murphy & Presser, 400 Garden City Plaza, Garden City, NY, 11530, US

(21) Appl. No.: 09/741,412

(22) Filed: Dec. 20, 2000

(30) Foreign Application Priority Data
Dec. 28, 1999 (JP) 374483/1999

(51) Int. Cl. H01L 21/302; H01L 21/461

(52) U.S. Cl. 438/689

(57) ABSTRACT

The present invention relates to a slurry used for chemical mechanical polishing of a substrate having an insulating film and a tantalum-containing metal film formed on the insulting film, which slurry contains a silica abrasive and a polycarboxylic acid such as oxalic acid, malonic acid, tartaric acid, malic acid, glutaric acid, citric acid, maleic acid or the like. According to the present invention, a buried electric connection of high reliability and excellent electrical properties can be formed at a high polishing rate, i.e. at a high throughput with the generation of dishing and erosion being suppressed.

### BACKGROUND OF THE INVENTION

1. Field of the Invention

The present invention relates to a slurry for chemical mechanical polishing, used in production of semiconductor device. More particularly, the present invention relates to a slurry for chemical mechanical polishing, suitably used for formation of a buried metal interconnect (damascene interconnect) by using a tantalum-containing metal as a barrier metal film material.

2. Description of the Related Art

With regard to forming a semiconductor integrated circuit such as ULSI which has been significantly refined and compacted, copper has been expected to be a useful material for electric connection because of its good electromigration resistance and lower electrical resistance.

To date a copper interconnect is formed as follows due to problems such as difficulty in patterning by dry etching. Specifically, a concave such as a groove and a connection hole is formed in an insulating film, a barrier metal film is formed on the surface, a copper film is deposited over the surface by plating such that the concave is filled with the material, and then the surface is polished to be flat by chemical mechanical polishing (hereinafter, referred to as “CMP”) until the surface of the insulating film except the concave area is completely exposed, to form electric connections such as a damascene interconnect in which the concave is filled with copper, a via plug and a contact plug.

There will be described a process for forming a damascene copper interconnect with reference to FIG. 1.

First, on a silicon substrate (not shown in FIG. 1) on which semiconductor elements are formed, is formed a lower wiring layer 1 comprising an insulating film having lower wirings (not shown in FIG. 1). As shown in FIG. 1(a), thereon are formed a silicon nitride film 2 and a silicon oxide film 3 in this order. Then, in the silicon oxide film 3 are formed a concave having an interconnect pattern and reaching the silicon nitride film 2.

Next, as shown in FIG. 1(b), a barrier metal film 4 is formed by sputtering. Then, on the whole surface is formed a copper film 5 by plating such that the concave is filled with the material.

Thereafter, as shown in FIG. 1(c), the copper film 5 is polished by CMP to make the substrate surface flat. Polishing by CMP is continued until the metal over the silicon oxide film 3 is completely removed, as shown in FIG. 1(d).

In the above process for forming a damascene copper interconnect, a barrier metal film is formed as a base film for, e.g., preventing diffusion of copper into the insulating film. When a tantalum-containg metal such as Ta, TaN or the like is used as the material for the barrier metal film, however, the polishing rate of the barrier metal film made of Ta or TaN, as compared with that of the copper film formed on the barrier metal film, is strikingly small in CMP using a conventional polishing slurry, because Ta or TaN is very stable chemically. That is, when a damascene copper interconnect or the like are formed by CMP using a conventional polishing slurry, dishing or erosion takes place because there is a significant difference between the polishing rates for the barrier metal film and the copper film.

Dishing is a phenomenon that the copper in the concave is excessively polished so that the center of the copper film in the concave is depressed in relation to the plane of the insulating film on the substrate, as shown in FIG. 2. CMP using a conventional polishing slurry requires an adequately much polishing time for completely removing the barrier metal film 4 on the insulating film (silicon oxide film 3) because of a lower polishing rate for the barrier metal film. The polishing rate for the copper film 5 is higher than that for the barrier metal film 4, so that the copper film is excessively polished, resulting in dishing.

Erosion is a phenomenon that polishing in a dense interconnect area excessively proceeds in relation to that in a sparse area such as an isolated interconnect area so that the surface of the dense interconnect area becomes depressed in relation to the other surfaces, as shown in FIG. 1(d). When the dense interconnect area comprising many damascenes of the copper film 5 is considerably separated from the isolated interconnect area comprising less damascenes of the copper film 5 by, for example, an area without interconnects within the wafer, and the copper film 5 is polished faster than the barrier metal film 4 or the silicon oxide film 3 (insulating film), then a polishing pad pressure to the barrier metal film 4 or the silicon oxide film 3 in the dense interconnect area becomes higher than that in the isolated interconnect area. As a result, in the CMP process after exposing the barrier metal film 4 (the process of FIG. 1(c) and thereafter), there generates a difference in a polishing rate between the dense interconnect area and the isolated interconnect area, so that the insulating film in the dense interconnect area is excessively polished, resulting in erosion.

Dishing in the process for forming an electric connection in a semiconductor device as described above, may cause increase in an interconnection resistance and a contact resistance, and tends to cause electromigration, leading to poor reliability in the device. Erosion may adversely affect flatness in the substrate surface, which becomes more prominent in a multilayer structure, causing problems such as increase and dispersion in an interconnect resistance.

JP-A 8-83780 has described that dishing in a CMP process may be prevented by using a polishing slurry containing benzotriazole or its derivative and forming a protective film on a copper surface. JP-A 11-238709 has also described that a triazole compound is effective for preventing dishing. The technique, however, controls dishing by reducing a polishing rate for a copper film. Thus, a difference in a polishing rate between a copper film and a barrier metal film may be reduced, but polishing of the copper film takes a longer time, leading to a lower throughput.

JP-A 10-44047 has described in its Examples that CMP may be conducted using a polishing slurry containing an alumina polishing material, ammonium persulfate (an oxidizing agent) and a particular carboxylic acid to increase a difference in a polishing rate between an aluminum layer for interconnection and a silicon oxide film and to increase a removal rate for a titanium film as a barrier metal film. The approach by the above Examples, however, could not solve the above-mentioned problem in formation of a buried copper interconnect using a tantalum-containing metal film as a barrier metal film.

JP-A 10-46140 has described a polishing composition comprising a particular carboxylic acid, an oxidizing agent and water whose pH is adjusted by an alkali to 5 to 9. Examples in the publication have disclosed a polishing composition containing malic acid, citric acid, tartaric acid or oxalic acid as a carboxylic acid and aluminum oxide as a polishing material (Examples 1 to 4, 7, 8 and 11) and a polishing composition comprising malic acid as a carboxylic acid and silicon oxide as a polishing material (Example 12). However, this publication has described only improvement in a polishing rate and prevention of occurring dishing associated with a corrosion mark as an effect of addition of a carboxylic acid such as citric acid, and there are no descriptions for polishing a tantalum-containing metal film or erosion.

JP-A 10-163141 has disclosed a polishing composition for a copper film containing a polishing material and water, further comprising an iron (III) compound dissolved in the composition. Examples in the publication has described that a polishing rate for a copper film may be improved and surface defects such as dishing and scratches may be prevented, by using colloidal silica as a polishing material and iron (III) citrate, ammonium iron (III) citrate or ammonium iron (III) oxalate as an iron (III) compound. This publication has no descriptions about polishing for a tantalum-containing metal.

JP-A 11-21546 has disclosed a slurry for chemical mechanical polishing comprising urea, a polishing material, an oxidizing agent, a film-forming agent and a complex-forming agent. Examples in this publication have described polishing Cu, Ta and PTEOS using a slurry having pH 7.5 prepared using alumina as a polishing material, hydrogen peroxide as an oxidizing agent, benzotriazole as a film-forming agent and tartaric acid or ammonium oxalate as a complex-forming agent. However, the result shown in Table 6 indicates very large difference between Cu-removal rate and Ta-removal rate. The publication has described only that addition of the complex-forming agent such as tartaric acid and ammonium oxalate is effective for disturbing a passive layer formed by a film-forming agent such as benzotriazole and for limiting a depth of an oxidizing layer. There are no descriptions about polishing for a tantalum-containing metal.

### SUMMARY OF THE INVENTION

An object of the present invention is to provide a slurry for chemical mechanical polishing which is used for polishing of a substrate having an insulating film and a tantalum-containing metal film formed on the insulting film and which can form a buried electric connection of high reliability and excellent electrical properties at a high polishing rate while suppressing the generation of dishing or erosion.

The present invention relates to A slurry used for chemical mechanical polishing of a substrate having an insulating film and a tantalum-containing metal film formed on the insulting film, which slurry contains a silica abrasive and a carboxylic acid represented by the following chemical formula (1):

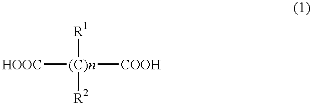

where n is 0, 1, 2 or 3, and each R¹ and R² is, independently for a carbon atom to which it attaches, hydrogen, —OH or —COOH; or chemical formula (2):

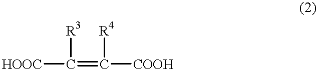

where each of R³ and R⁴ is independently a hydrogen or —OH.

By using the polishing slurry of the present invention in chemical mechanical polishing of a substrate having an insulating film and a tantalum-containing metal film formed on the insulting film, there can be formed a buried electric connection of high reliability and excellent electrical properties at a high polishing rate, i.e. at a high throughput while suppressing the generation of dishing or erosion.

### BRIEF DESCRIPTION OF THE DRAWINGS

FIG. 1 is a process cross section illustrating a process for forming a buried copper interconnect according to the prior art.

FIG. 2 is a drawing showing the shape of the section of a copper interconnect formed using a conventional slurry for chemical mechanical polishing.

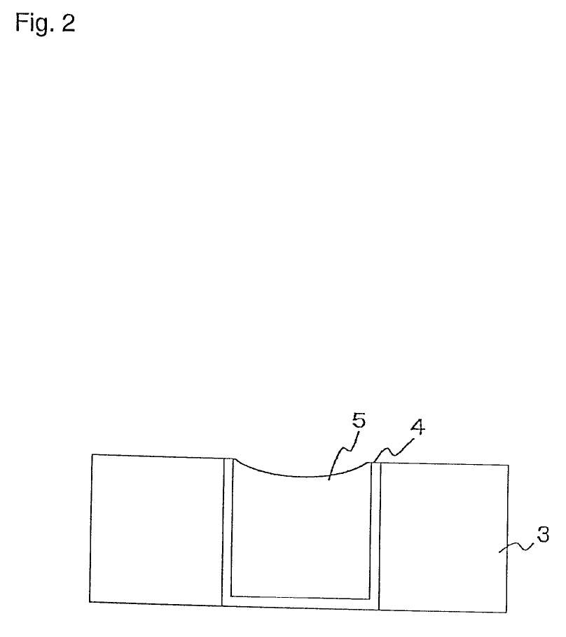

### DETAILED DESCRIPTION OF THE PREFERRED EMBODIMENTS

Preferred embodiments of the present invention are described below.

The slurry for chemical mechanical polishing (hereinafter referred to as “the polishing slurry” in some cases) according to the present invention is suitable for polishing of a tantalum-containing metal film made of tantalum (Ta), tantalum nitride (TaN) or the like, formed on an insulating film. It can be suitably used particularly in polishing, by CMP, a substrate comprising an insulating film having a concave, a barrier metal film made of a tantalum-containing metal, formed on the insulating film, and a conductive metal film formed thereon so as to fill the concave, to form an electric connection such as buried interconnects having a barrier metal film made of a tantalum-containing metal, plugs, contacts or the like. The polishing slurry of the present invention may also be used, in CMP, from the time when a conductive metal film has been polished and a tantalum-containing metal film has been exposed.

By conducting CMP using the polishing slurry of the present invention, buried electric connections of high reliability and excellent electrical properties can be formed at a high polishing rate, i.e. at a high throughput with the generation of dishing and erosion being suppressed.

The polishing slurry of the present invention comprises a silica abrasive (grain), a carboxylic acid represented by the above formula (1) or (2) and water. An oxidizing agent is preferably contained for enhancing polishing the interconnect metal film formed on the barrier metal film.

As the silica abrasive, polishing grains consisting of silicon dioxide may be used; for example, fumed silica and colloidal silica. A silica abrasive may be prepared by a variety of known processes; for example, fumed silica by vapor phase synthesis via reaction of silicon tetrachloride in a flame of oxygen and hydrogen, and silica prepared by hydrolyzing a metal alkoxide in a liquid phase and then baking it. In manufacturing a semiconductor device, among these polishing grains consisting of silicon dioxide, fumed silica is preferable because of its lower price and its lower Na content as an impurity.

An average particle size (diameter) of the silica abrasive is preferably at least 5 nm, more preferably at least 50 nm, and also preferably 500 nm or less, more preferably 300 nm or less as determined by a light scattering diffraction technique. A particle size distribution is preferably 3 μm or less, more preferably 1 μm or less for the maximum particle size (d100). A specific surface area is preferably at least 5 m²/g, more preferably at least 20 m²/g and also 1000 m²/g or less, more preferably 500 m²/g or less as determined by B.E.T.

A content of the silica abrasive in the polishing slurry may be appropriately selected within the range of 0.1 to 50 wt % to the total amount of the slurry composition in the light of factors such as a polishing efficiency and polishing accuracy. It is preferably at least 1 wt %, more preferably at least 2 wt %, further preferably at least 3 wt % while an upper limit may be preferably 30 wt %, more preferably 10 wt %, further preferably 8 wt %.

The carboxylic acid represented by the formula (1) or (2), used in the polishing slurry of the present invention is one having two or more carboxyl groups in one molecule; for example, oxalic acid, malonic acid, tartaric acid, malic acid, glutaric acid, citric acid, maleic acid and their salts as well as a mixture of two or more of them.

The content of the above particular carboxylic acid used in the present polishing slurry is preferably at least 0.01 wt %, more preferably at least 0.05 wt % to the total amount of the slurry composition for improving a polishing rate for the tantalum-containing metal film while it is preferably 1 wt % or less, more preferably 0.8 wt % or less for preventing thixotropy in the polishing slurry.

The polishing slurry of the present invention comprising silica polishing grains as an abrasive and a particular carboxylic acid represented by the formula (1) or (2) may significantly improve a polishing rate for the tantalum-containing metal film while preventing generation of scratches in a polished surface. Thus, a difference in a polishing rate between the barrier metal film and the interconnect metal film can be minimized by improving a polishing rate for the tantalum-containing metal film, so that dishing and erosion can be prevented to allow us to form a good damascene interconnect without reducing a throughput.

It is believed that the polycarboxylic acid represented by the formula (1) or (2), used in the present invention aggregates silica particles dispersed in water (flocculation) and the aggregated silica particles by the carboxylic acid enhance mechanical effect, resulting in good polishing of the tantalum-containing metal film. The aggregation may be properly weak and relatively soft aggregated particles may be formed, so that a polishing rate for the tantalum-containing metal film can be improved while preventing scratches in the polished surface.

In the light of a polishing rate and corrosion, a slurry viscosity and dispersion stability of polishing grains, a polishing slurry of the present invention has a pH of preferably at least 4, more preferably at least 5 and preferably 8 or less, more preferably 7 or less.

For the polishing slurry, pH may be adjusted by a known technique. For example, an alkali may be directly added to a slurry in which polishing grains are dispersed and an carboxylic acid is dissolved. Alternatively, a part or all of an alkali to be added may be added as an carboxylic acid alkali salt. Examples of an alkali which may be used include alkali metal hydroxides such as sodium hydroxide and potassium hydroxide; alkali metal carbonates such as sodium carbonate and potassium carbonate; ammonia; and amines.

It is preferable to add an oxidizing agent to the polishing slurry of the present invention for enhancing polishing of the conductive metal film on a barrier metal film. The oxidizing agent may be appropriately selected from known water-soluble oxidizing agents in the light of a type of a interconnect conductive metal film, polishing accuracy and a polishing efficiency. For example, those which may not cause heavy-metal ion contamination include peroxides such as H₂O₂, Na₂O₂, Ba₂O₂ and (C₆H₅C)₂O₂; hypochlorous acid (HClO); perchloric acid; nitric acid; ozone water; and organic acid peroxides such as peracetic acid and nitrobenzene. Among these, hydrogen peroxide (H₂O₂) is preferable because it does not contain a metal component and does not generate a harmful byproduct. The content of the oxidizing agent in the polishing slurry of the present invention is preferably at least 0.01 wt %, more preferably at least 0.05 wt % for achieving adequate effects of its addition while it is preferably 15 wt % or less, more preferably 10 wt % or less for preventing dishing and adjusting a polishing rate to a proper value. When using an oxidizing agent which is relatively susceptible to deterioration with age such as hydrogen peroxide, it may be possible to separately prepare a solution containing an oxidizing agent at a given concentration and a composition which provides a given polishing slurry after addition of the solution containing an oxidizing agent, which are then combined just before use.

An organic acid such as known carboxylic acids and amino acids may be added as a proton donor for enhancing oxidization by the oxidizing agent and achieving stable polishing. Although a polycarboxylic acid represented by formula (1) or (2) may act as such a proton donor, a different organic acid such as a carboxylic acid and an amino acid may be added.

Carboxylic acids other than a carboxylic acid represented by formula (1) or (2) include formic acid, acetic acid, propionic acid, butyric acid, valeric acid, acrylic acid, lactic acid, succinic acid, nicotinic acid and their salts.

An amino acid may be added as such, as a salt or as a hydrate. Examples of those which may be added include arginine, arginine hydrochloride, arginine picrate, arginine flavianate, lysine, lysine hydrochloride, lysine dihydrochloride, lysine picrate, histidine, histidine hydrochloride, histidine dihydrochloride, glutamic acid, glutamic acid hydrochloride, sodium glutaminate monohydrate, glutamine, glutathione, glycylglycine, alanine, β-alanine, γ-aminobutyric acid, ε-aminocarproic acid, aspartic acid, aspartic acid monohydrate, potassium aspartate, potassium aspartate trihydrate, tryptophan, threonine, glycine, cystine, cysteine, cysteine hydrochloride monohydrate, oxyproline, isoleucine, leucine, methionine, ornithine hydrochloride, phenylalanine, phenylglycine, proline, serine, tyrosine, valine, and a mixture of these amino acids.

The content of the organic acid is preferably at least 0.01 wt %, more preferably at least 0.05 wt % to the total amount of the polishing slurry for achieving adequate effects of its addition, while it is preferably 5 wt % or less, more preferably 3 wt % or less as a content including the carboxylic acid represented by formula (1) or (2) for preventing dishing and adjusting a polishing rate to a proper value.

When adding an oxidizing agent in a polishing slurry, an antioxidant may be further added. Addition of an antioxidant may allow a polishing rate for a interconnect conductive metal film to be easily adjusted and may result in forming a coating film over the surface of the interconnect conductive metal film to prevent dishing.

Examples of an antioxidant include benzotriazole, 1,2,4-triazole, benzofuroxan, 2,1,3-benzothiazole, o-phenylenediamine, m-phenylenediamine, cathechol, o-aminophenol, 2-mercaptobenzothiazole, 2-mercaptobenzimidazole, 2-mercaptobenzoxazole, melamine, and their derivatives. Among these, benzotriazole and its derivatives are preferable. Examples of a benzotriazole derivative include substituted benzotriazoles having a benzene ring substituted with hydroxy; alkoxy such as methoxy and ethoxy; amino; nitro; alkyl such as methyl, ethyl and butyl; halogen such as fluorine, chlorine, bromine and iodine. Furthermore, naphthalenetriazole and naphthalenebistriazole as well as substituted naphthalenetriazoles and substituted naphthalenebistriazoles substituted as described above may be used.

The content of the antioxidant is preferably at least 0.0001 wt %, more preferably at least 0.001 wt % to the total amount of the polishing slurry for achieving adequate effects of its addition, while it is preferably 5 wt % or less, more preferably 2.5 wt % or less for adjusting a polishing rate to a proper value.

The polishing slurry of the present invention may contain a variety of additives such as dispersing agents, buffers and viscosity modifiers commonly added to a polishing slurry as long as it does not deteriorate the properties of the slurry.

In the polishing slurry of the present invention, the component ratio is preferably controlled so that the polishing rate of tantalum-containing metal film becomes preferably 20 nm/min or more, more preferably 30 nm/min or more, further preferably 40 nm/min or more. Further, the component ratio of the present polishing slurry is preferably controlled so that the polishing rate of copper becomes preferably 30 nm/min or more, more preferably 40 nm/min or more, further preferably 50 nm/min or more. Furthermore, the component ratio of the present polishing slurry is preferably controlled so that the ratio of the polishing rate of copper film and the polishing rate of tantalum-containing metal film, i.e. the Cu/Ta polishing ratio becomes preferably 3/1 or less, more preferably 2/1 or less, further preferably 1.5/1 or less, and preferably 0.9/1 or more, more preferably 1/1 or more. In addition, the component ratio of the present polishing slurry is desirably controlled so that the ratio of the polishing rate of tantalum-containing metal film and the polishing rate of inter-layer insulating film, i.e. the Ta/insulating film polishing ratio is as large as possible, that is, preferably 10/1 or more, more preferably 20/1 or more, further preferably 30/1. The upper limit is not particularly restricted, but is controlled at 100/1 or less, or even at 200/1 or less.

The polishing slurry of the present invention may be prepared by a common process for preparing a free grain polishing slurry. Specifically, polishing grain particles are added to a dispersion medium to an appropriate amount. A protective agent may be, if necessary, added to an appropriate amount. In such a state, air is strongly adsorbed in the surface of the grain particles, so that the grains are aggregated due to poor wettability. Thus, the aggregated polishing material particles are dispersed into primary particles. In a dispersion process, a dispersion technique and a dispersion apparatus commonly used may be employed. Specifically, dispersion may be conducted using an apparatus such as an ultrasonic disperser, a variety of bead mill dispersers, a kneader and a ball mill by a known process. A carboxylic acid represented by formula (1) or (2) may cause flocculation of silica particles while enhancing thixotropy. It is, therefore, preferable to add and mix the component after dispersion for achieving good dispersion.

CMP using the polishing slurry of the present invention can be conducted, for example, as follows. A wafer on which an insulating film and a copper-containing metal film is deposited is placed on a spindle wafer carrier. The surface of the wafer is contacted with a polishing pad adhered on a rotary plate (surface plate). While supplying a polishing slurry to the surface of the polishing pad from a polishing slurry inlet, both the wafer and the polishing pad are rotated to polish the wafer. If necessary, a pad conditioner is contacted with the surface of the polishing pad to condition the surface of the polishing pad. Incidentally, the feeding of the polishing slurry to the polishing pad surface may be conducted from the rotary plate side.

The polishing slurry of the present invention is suitably used in polishing, by CMP, a substrate comprising an insulating film having concaves (e.g. grooves or contact holes), a tantalum-containing metal film formed on the insulating film as a barrier metal film, and a conductive metal film formed thereon so as to fill the concaves until the surface of the insulating film other than that in the concaves is almost completely exposed, to form an electric connection such as buried interconnects, via plugs, contact plugs or the like. As the insulating film, there can be mentioned a silicon oxide film, a BPSG film, a SOG film, etc.; as the conductive metal film, there can be mentioned a copper film, a silver film, a gold film, a platinum film, a titanium film, a tungsten film, an aluminum film, and films made of their alloys. The polishing slurry of the present invention is particularly suitable when the conductive metal film is a copper film or a film of a copper alloy containing copper as the main component.

### EXAMPLES

The present invention is described in more detail below by way of Examples.

### Compositions of Polishing Slurries

Reagents produced by Kanto Chemical Co., Inc. were used for glutaric acid, citric acid, malic acid, tartaric acid, oxalic acid, maleic acid, malonic acid and benzotriazole. A 34% aqueous hydrogen peroxide solution reagent produced by Kanto Chemical Co., Inc. was used for hydrogen peroxide. Fumed silica Qs-9 produced by Tokuyama Sha was used for silica. Using these components, polishing slurries having compositions shown in Tables 1 to 4 were produced according to an ordinary method.

### CMP Conditions

CMP was conducted using a Speedfam-Ipec Type 372 apparatus. The polisher was used, on whose surface plate a polishing pad (Rodel-Nitta IC 1400) was attached. Polishing conditions were as follows: a polishing load (a contact pressure of the polishing pad): 27.6 kPa; a rotating speed of the surface plate: 55 rpm; a carrier rotating speed: 55 rpm; and a polishing slurry feeding rate: 100 mL/min.

### Determination of a Polishing Rate

Polishing rate was calculated form surface resistivities before and after polishing. Specifically, four needle electrodes were aligned on a wafer with a given interval. A given current was applied between the outer two probes to detect a potential difference between two inner probes for determining a resistance (R′) and further the value is multiplied by a correction factor RCF (Resistivity Correction Factor) to a surface resistivity (ρs′). A surface resistivity (ρs) is determined for a wafer film whose thickness (T) (nm) is known. The surface resistivity is inversely proportional to the thickness. Thus, when a thickness for a surface resistivity of ρs′ is d, an equation d(nm)=(ρs×T)/ρ s′ holds true. Using the equation, the thickness d can be determined. Furthermore, a variation of thickness between before and after polishing was divided by a polishing time to estimate a polishing rate. A surface resistivity was determined using Mitsubishi Chemical Industries Four Probe Resistance Detector (Loresta-GP).

### Example 1

In order to examine, in CMP for tantalum-containing metal film, the addition effect of the carboxylic acid of the formula (1) or (2) in the polishing slurry used, CMP was conducted for a Ta film formed on a 6-in. silicon substrate by sputtering, using various polishing slurries, and respective polishing rates were measured.

The addition effects of carboxylic acid in the polishing slurry, on Ta polishing rate are shown in Tables 1 to 3. Table 1 shows results when there were used various polishing slurries containing glutaric acid as the carboxylic acid in different amounts. Table 2 shows results when there were used various polishing slurries containing glutaric acid as the carboxylic acid but having different pHs and using different pH-adjusting agents. Table 3 shows results when there were used various polishing slurries containing different carboxylic acids.

As seen from Table 1, addition of glutaric acid significantly improved a polishing rate for the Ta film and as the amount (content) of glutaric acid added increased, the polishing rate increased.

Furthermore, the appearance of the polishing slurry was changed by adding glutaric acid from translucent to cloudy. This indicated that a scattering intensity increased due to particles with a large size by aggregation. From the results it is suspected that addition of a carboxylic acid caused increase in an ion strength in the solution, which pressed an electric double layer, leading to reduction in an electric repulsion between particles while aggregation (flocculation) occurred due to interaction between the carboxylic acid having two or more carboxyl groups in one molecule and the silica particle, and properly soft silica aggregates formed by the aggregation acted as polishing grains to enhance mechanical polishing and thus to improve the polishing rate of the Ta film.

As shown in Tables 1 and 2, polishing could be conducted with a higher polishing rate even when pH of the polishing slurry was varied within the range of 4.5 to 6.5. The results shown in Table 2 indicate that a similarly higher polishing rate was achieved even when replacing the pH regulator from KOH to NH₄OH.

The results in Table 3 show that in place of glutaric acid, a polycarboxylic acid having a particular structure represented by formula (1) or (2) may improve a polishing rate for the Ta film. Furthermore, adding any carboxylic acid shown in the table changed the appearance of the polishing slurry from translucent to cloudy.

TABLE 1

| | Polishing | Carboxylic | | | Ta polishing |
|---|---|---|---|---|---|
| Slurry | material | acid | pH | | rate |
| No. | (content/wt %) | (content/wt %) | regulator | pH | (nm/min) |
| 1 | Fumed silica | — | KOH | 6.5 | 12.1 |
| | (5) | | | | |
| 2 | Fumed silica | Glutaric acid | KOH | 6.5 | 29.2 |
| | (5) | (0.02) | | | |
| 3 | Fumed silica | Glutaric acid | KOH | 6.5 | 29.3 |
| | (5) | (0.04) | | | |
| 4 | Fumed silica | Glutaric acid | KOH | 6.5 | 42.3 |
| | (5) | (0.08) | | | |
| 5 | Fumed silica | Glutaric acid | KOH | 6.5 | 46.5 |
| | (5) | (0.16) | | | |
| 6 | Fumed silica | Glutaric acid | KOH | 6.5 | 56.5 |
| | (5) | (0.27) | | | |

TABLE 2

| | Polishing | Carboxylic | | | Ta polishing |
|---|---|---|---|---|---|
| Slurry | material | acid | pH | | rate |
| No. | (content/wt %) | (content/wt %) | regulator | pH | (nm/min) |
| 7 | Fumed silica | Glutaric acid | KOH | 4.5 | 51.2 |
| | (5) | (0.16) | | | |
| 8 | Fumed silica | Glutaric acid | KOH | 5.0 | 52.5 |
| | (5) | (0.16) | | | |
| 9 | Fumed silica | Glutaric acid | KOH | 5.5 | 50 |
| | (5) | (0.16) | | | |
| 10 | Fumed silica | Glutaric acid | NH₄OH | 4.5 | 50.9 |
| | (5) | (0.16) | | | |
| 11 | Fumed silica | Glutaric acid | NH₄OH | 5.0 | 52.1 |
| | (5) | (0.16) | | | |
| 12 | Fumed silica | Glutaric acid | NH₄OH | 5.5 | 49.3 |
| | (5) | (0.16) | | | |

TABLE 3

| | Polishing | | | | Ta polishing |
|---|---|---|---|---|---|
| Slurry | material | Carboxylic acid | pH | | rate |
| No. | (content/wt %) | (content/wt %) | regulator | pH | (nm/min) |
| 13 | Fumed silica | Malic acid | KOH | 5.5 | 58.8 |
| | (5) | (0.536) | | | |
| 14 | Fumed silica | Tartaric acid | KOH | 5.5 | 36.1 |
| | (5) | (0.6) | | | |
| 15 | Fumed silica | Maleic acid | KOH | 5.5 | 36.2 |
| | (5) | (0.46) | | | |
| 16 | Fumed silica | Malonic acid | KOH | 5.5 | 46.9 |
| | (5) | (0.416) | | | |
| 17 | Fumed silica | Oxalic acid | KOH | 5.5 | 48.2 |
| | (5) | (0.36) | | | |
| 18 | Fumed silica | Citric acid | KOH | 6.5 | 97.1 |
| | (5) | (0.33) | | | |

### Example 2

CMP was conducted using polishing slurries of the present invention, to form buried copper interconnects each using a Ta film as the barrier metal film.

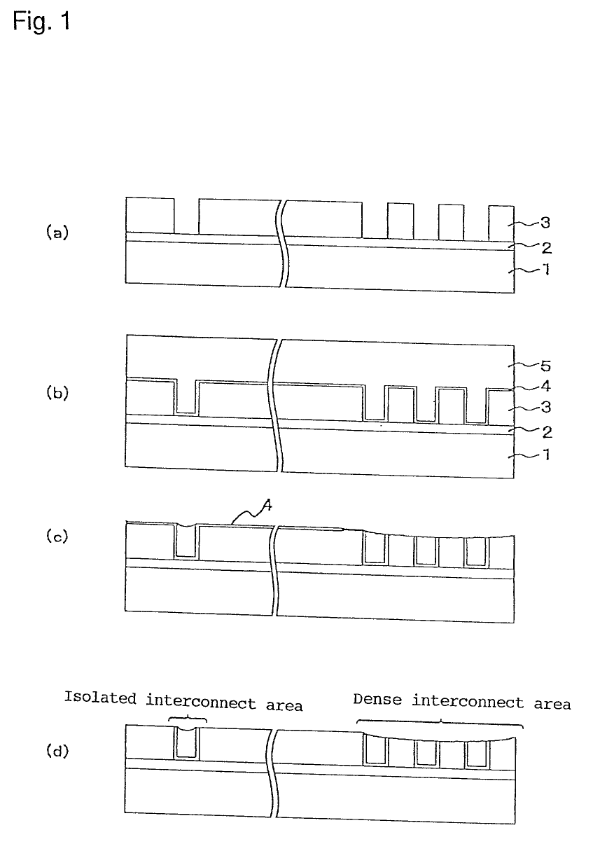

On a 6 inch wafer (silicon substrate, not shown) in which a semiconductor device such as a transistor was formed was deposited a lower interconnect layer 1 made of a silicon oxide film comprising a lower interconnect (not shown). On the lower interconnect layer was, as shown in FIG. 1(a), formed a silicon nitride film 2, on which was formed a silicon oxide film 3 with a thickness of about 500 nm. The silicon oxide film 3 was patterned by photolithography and reactive ion etching as usual to form a groove for interconnection and a connection hole with a width of 0.23 to 10 μm and a depth of 500 nm. Then, as shown in FIG. 1(b), Ta film (tantalum film) 4 was formed to a thickness of 50 nm by sputtering, a copper film was formed to a thickness of about 50 nm by sputtering, and then a copper film was formed to a thickness of about 800 nm by plating. The thus-produced substrate was subjected to CMP using various polishing slurries.

In Table 4 are shown the compositions of various polishing slurries each different in polishing rates for the copper film, Ta film and silicon oxide film of the substrate, and the polishing rates of these slurries.

These results show that a polishing rate ratio between the Ta film and the copper film may be adjusted by varying a composition ratio among the carboxylic acid represented by formula (1) or (2) or a mixture thereof, the oxidizing agent (H₂O₂) and the antioxidant (benzotriazole (BTA)). In the prior art, a polishing rate is adjusted by reducing a polishing rate for a copper film, while in this invention, the polishing rate may be also adjusted (i.e., reduction in a polishing rate difference) by increasing the Ta film, to considerably improve a throughput.

Using the polishing slurries shown in Table 4, CMP was conducted to form buried copper interconnects and contacts. In using any of the polishing slurries, polishing was possible at a high Ta polishing rate, a good Cu/Ta polishing rate ratio and a low SiO₂ polishing rate. As a result, there was no dishing or erosion in a dense interconnect area and there was no dishing (recess) in an isolated interconnect area. The results show that a properly small difference in polishing rates between the copper film and the Ta film prevented excessive polishing of the copper film and the insulating film has a polishing rate adequately low to act as a stopper for preventing dishing and erosion. Observation of the polished surface by SEM indicated no significant scratches.

TABLE 4

| | Polishing | | Anti- | Oxidizing | | | Ta | Cu | SiO₂ |
|---|---|---|---|---|---|---|---|---|---|
| | material | Carboxylic | oxidant | agent | | | polishing | polishing | polishing |
| Slurry | (content/ | acid | (content/ | (content/ | pH | | rate | rate | rate |
| No. | wt %) | (content/wt %) | wt %) | wt %) | regulator | pH | (nm/min) | (nm/min) | (nm/min) |
| 19 | Fumed | Glutaric acid | Bta | H₂O₂ | KOH | 4.5 | 45.3 | 50.3 | 2.0 |
| | silica | (0.16) | (0.005) | (0.093) | | | | | |
| | (8) | | | | | | | | |
| 20 | Fumed | GLU(0.16) + | BTA | H₂O₂ | KOH | 6.0 | 37 | 80.2 | 2.0 |
| | silica | CIT(0.05)* | (0.005) | (1.53) | | | | | |
| | (8) | | | | | | | | |
| 21 | Fumed | Citric acid | BTA | H₂O₂ | KOH | 6.0 | 47 | 55.6 | 2.0 |
| | silica | (0.05) | (0.005) | (1.53) | | | | | |
| | (8) | | | | | | | | |

*GLU: Glutaric acid; CIT: Citric acid

What is claimed is:

1. A slurry used for chemical mechanical polishing of a substrate having an insulating film and a tantalum-containing metal film formed on the insulting film, which slurry contains a silica abrasive and a carboxylic acid represented by the following chemical formula (1): 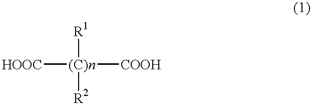
where n is 0, 1, 2 or 3, and each R¹ and R² is, independently for a carbon atom to which it attaches, hydrogen, —OH or —COOH; or chemical formula (2): 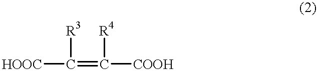
where each of R³ and R⁴ is independently a hydrogen or —OH.

2. A slurry used for chemical mechanical polishing according to claim 1, wherein the carboxylic acid is at least one kind selected from the group consisting of oxalic acid, malonic acid, tartaric acid, malic acid, glutaric acid, citric acid and maleic acid.

3. A slurry used for chemical mechanical polishing according to claim 1, having a pH of 4 to 8.

4. A slurry used for chemical mechanical polishing according to claim 1, wherein the content of the carboxylic acid is 0.01 to 1 wt %.

5. A slurry used for chemical mechanical polishing according to claim 1, wherein the content of the silica abrasive is 1 to 30 wt %.

6. A slurry used for chemical mechanical polishing according to claim 1, wherein the substrate has an insulating film having a concave, a tantalum-containing metal film formed on the insulating film as a barrier metal film, and a conductive metal film formed so as to fill the concave.

7. A slurry used for chemical mechanical polishing according to claim 6, wherein the conductive metal film is a copper film or a copper alloy film.

8. A slurry used for chemical mechanical polishing according to claim 1, further containing an oxidizing agent.

9. A slurry used for chemical mechanical polishing according to claim 1, further containing an oxidizing agent and an antioxidant.

10. A slurry used for chemical mechanical polishing according to claim 1, further containing an oxidizing agent and benzotriazole or its derivative.
